(19) United States
(12) Patent Application Publication
(10) Pub. No.: US 2017/0162749 A1
(43) Pub. Date: Jun. 8, 2017

(54) OPTOELECTRONIC SEMICONDUCTOR CHIP AND METHOD OF PRODUCING SAME

(71) Applicant: OSRAM Opto Semiconductors GmbH, Regensburg (DE)

(72) Inventors: Wolfgang Schmid, Regensburg (DE); Petrus Sundgren, Lappersdorf (DE)

(73) Assignee: OSRAM Opto Semiconductors GmbH, Regensburg (DE)

(21) Appl. No.: 15/309,938

(22) PCT Filed: May 20, 2015
(86) PCT No.: PCT/EP2015/061040

§ 371 Date: Nov. 9, 2016

(30) Foreign Application Priority Data
May 26, 2014 (DE) 10 2014 107 385.1

(51) Int. Cl. H01L 33/22; H01L 21/66; H01L 33/38; H01L 33/00; H01L 33/06; H01L 33/30

(52) U.S. Cl. CPC H01L 33/22; H01L 33/06; H01L 33/30; H01L 33/387; H01L 33/0062; H01L 22/26

(57) ABSTRACT

An optoelectronic semiconductor chip which is a light emitting diode includes a semiconductor layer sequence having an n-conducting layer sequence, a p-conducting layer sequence, an active zone, at least one etching signal layer, and an etching structure, wherein the etching structure extends at least right into the etching signal layer, the etching signal layer has a signal constituent, the active zone generates radiation and is based on InAlGaP or on InAlGaAs, the etching signal layer is situated in the p-conducting layer sequence and is based on In_{1-x-y}Al_{y}GaₓP or on In_{1-x-y}Al_{y}GaₓAs where x+y<1, the signal constituent is Ga and 0.005≦x≦0.2, the signal constituent is not present in the layer adjoining the etching signal layer in a direction toward the etching structure, a thickness of the etching signal layer is 50 nm to 800 nm.

### TECHNICAL FIELD

This disclosure relates to an optoelectronic semiconductor chip and a method of producing such a semiconductor chip.

### BACKGROUND

It could be helpful to provide an optoelectronic semiconductor chip having an efficient coupling-out of light.

### SUMMARY

We provide an optoelectronic semiconductor chip which is a light emitting diode including a semiconductor layer sequence, wherein the semiconductor layer sequence has an n-conducting layer sequence, a p-conducting layer sequence, an active zone situated between the n-conducting layer sequence and the p-conducting layer sequence, at least one etching signal layer in the p-conducting layer sequence and/or in the n-conducting layer sequence, and an etching structure at a side of the etching signal layer facing away from the active zone, wherein the etching structure extends at least right into the etching signal layer, the etching signal layer has a signal constituent, the active zone generates radiation and is based on InAlGaP or on InAlGaAs, the etching signal layer is situated in the p-conducting layer sequence and is based on In_{1-x-y}Al_{y}GaₓP or on In_{1-x-y}Al_{y}GaₓAs where x+y<1, the signal constituent is Ga and 0.005≦x≦0.2, the signal constituent is not present in the layer adjoining the etching signal layer in a direction toward the etching structure, a thickness of the etching signal layer is 50 nm to 800 nm, and as a result of the etching structure a material of the etching signal layer is partly removed.

We also provide a method in which the optoelectronic semiconductor chip, which is a light emitting diode including a semiconductor layer sequence, wherein the semiconductor layer sequence has an n-conducting layer sequence, a p-conducting layer sequence, an active zone situated between the n-conducting layer sequence and the p-conducting layer sequence, at least one etching signal layer in the p-conducting layer sequence and/or in the n-conducting layer sequence, and an etching structure at a side of the etching signal layer facing away from the active zone, wherein the etching structure extends at least right into the etching signal layer, the etching signal layer has a signal constituent, the active zone generates radiation and is based on InAlGaP or on InAlGaAs, the etching signal layer is situated in the p-conducting layer sequence and is based on In_{1-x-y}Al_{y}GaₓP or on In_{1-x-y}Al_{y}GaₓAs where x+y<1, the signal constituent is Ga and 0.005≦x≦0.2, the signal constituent is not present in the layer adjoining the etching signal layer in a direction toward the etching structure, a thickness of the etching signal layer is 50 nm to 800 nm, and as a result of the etching structure a material of the etching signal layer is partly removed, is produced including providing the semiconductor layer sequence having the n-conducting layer sequence, the p-conducting layer sequence, the active zone and the etching signal layer, producing the etching structure by dry-chemical etching of the semiconductor layer sequence, and completing the semiconductor chip, wherein during the etching measurement is carried out toward the signal constituent of the etching signal layer, and the etching is ended by an evaluation of the measurement of the signal constituent.

We further provide an optoelectronic semiconductor chip including a semiconductor layer sequence, wherein the semiconductor layer sequence has an n-conducting layer sequence, a p-conducting layer sequence, an active zone situated between the n-conducting layer sequence and the p-conducting layer sequence, at least one etching signal layer in the p-conducting layer sequence and/or in the n-conducting layer sequence, an etching structure at a side of the etching signal layer facing away from the active zone, the etching structure extends at least right into the etching signal layer, and the etching signal layer has a signal constituent reduced by at least a factor of two in a layer adjoining the etching signal layer in a direction toward the etching structure.

### BRIEF DESCRIPTION OF THE DRAWINGS

FIGS. 1 to 5A-5B show schematic illustrations of examples of optoelectronic semiconductor chips.

### LIST OF REFERENCE SIGNS

1 optoelectronic semiconductor chip
2 semiconductor layer sequence
21 n-conducting layer sequence
22 active zone
23 p-conducting layer sequence
24 etching signal layer
25 p-type layer
26 ramp layer
3 etching structure
41 n-type electrode
43 p-type electrode
44 strip
45 electrical contact area
5 roughening
6 carrier
G growth direction

### DETAILED DESCRIPTION

Our optoelectronic semiconductor chip may be a light emitting diode or a laser diode. The semiconductor chip emits an electromagnetic radiation during operation. By way of example, visible light or near infrared radiation is generated during operation of the semiconductor chip. It is possible, in particular, for the semiconductor chip to generate yellow light, orange light and/or red light or generate near infrared radiation in the wavelength range of 760 nm to 870 nm.

The optoelectronic semiconductor chip may comprise at least one semiconductor layer sequence. In particular, the semiconductor layer sequence is grown epitaxially. The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or else an arsenide compound semiconductor material such as AlₙIn₁₋ₙ₋ₘAs, wherein 0≦n≦1, 0≦m≦1 and n+m≦1. The semiconductor layer sequence here may have dopants and additional constituents. For the sake of simplicity, however, only the essential constituents of the crystal lattice of the semiconductor layer sequence, that is to say Al, As, Ga, In, N or P, are indicated, even if they can be replaced and/or supplemented in part by small amounts of further substances.

The semiconductor layer sequence may comprise an n-conducting layer sequence. The n-conducting layer sequence is n-doped throughout or regionally. The n-conducting layer sequence can comprise one or a plurality of partial layers. Therefore, the term layer sequence does not necessarily mean that a plurality of layers must be present in the n-conducting layer sequence.

The semiconductor chip may comprise a p-conducting layer sequence comprising one or, preferably, a plurality of p-conducting layers. The p-conducting layer sequence is preferably p-doped.

The semiconductor chip may comprise at least one active zone. The one or the plurality of active zones are fitted between the n-conducting layer sequence and the p-conducting layer sequence. In particular, the active zone directly contacts the n-conducting layer sequence and the p-conducting layer sequence. The active zone comprises, for example, a pn junction, a single quantum well structure or a multiple quantum well structure. In particular, the active zone includes a plurality of quantum wells separated from one another by barrier layers.

The semiconductor layer sequence may include one or a plurality of etching signal layers. The at least one etching signal layer is situated in or at the p-conducting layer sequence or in the n-conducting layer sequence. If a plurality of etching signal layers are present, then respectively an etching signal layer can be present in the p-conducting layer sequence and an etching signal layer can be present in the n-conducting layer sequence. It is also possible for there to be a plurality of etching signal layers in one of the layer sequences.

The semiconductor chip may comprise one or a plurality of etching structures. In this case, the at least one etching structure extends at least right into the etching signal layer at least in relatively large regions or over the whole area. That means that as a result of the etching structure the etching signal layer is exposed at least in places and/or a material of the etching signal layer is at least partly removed when producing the etching structure. It is also possible for the etching signal layer to be removed completely across relatively large regions when producing the etching structure. By way of example, the etching structure has a prismatic or trapezoidal shape as seen in cross section, wherein a width of the etching structure preferably decreases in a direction toward the active zone.

The etching signal layer may have a signal constituent. The signal constituent is preferably a main component of a semiconductor material on which the etching signal layer is based. Alternatively, the signal constituent can be a doping of the etching signal layer.

The etching signal layer, in a direction toward the etching structure and in a direction away from the active zone, may adjoin a layer that is free of the signal constituent or has only little of the signal constituent. This means, in particular, that the signal constituent is present at most in the form of an impurity and/or that a concentration of the signal constituent in this layer, compared to the etching signal layer, is reduced by at least a factor of two or five or ten or one hundred. In other words, this layer is free of the signal constituent or has little of the signal constituent compared to the etching signal layer.

The signal constituent at the etching signal layer may have an atomic proportion of at least 0.5% or 1% or 1.75%. Alternatively or additionally, the proportion is at most 20% or 10% or 5% or 3.5%. In other words, the signal constituent then constituents only a comparatively small proportion of the etching signal layer.

The semiconductor chip may comprise a semiconductor layer sequence. The semiconductor layer sequence has an n-conducting layer sequence and also a p-conducting layer sequence and an active zone situated between these layer sequences to generate an electromagnetic radiation. Furthermore, in the semiconductor layer sequence at least one etching signal layer is situated in or at the p-conducting layer sequence and/or in or at the n-conducting layer sequence. Furthermore, an etching structure is situated at the semiconductor layer sequence at a side of the etching signal layer facing away from the active zone. In this case, the etching structure extends at least right into the etching signal layer at least in places. The etching signal layer has a signal constituent not present, or present only in a reduced concentration, in a layer adjoining the etching signal layer in a direction toward the etching structure and/or in a direction away from the active zone.

Particularly in thin-film light emitting diodes, that is to say in light emitting diodes without a growth substrate, light generated in an active zone propagates in a comparatively thin layer assembly in the semiconductor layer sequence until the generated light is either coupled out or absorbed. Since, owing to the high refractive index of semiconductor materials, a coupling-out probability per incidence of the light on a coupling-out area is comparatively low, light proceeds in the semiconductor for a relatively long time until coupling-out takes place. Accordingly, an efficiency of thin-film light emitting diodes is dependent to a comparatively great extent on absorptions in or at the semiconductor layer sequence.

In this case, an absorption takes place for instance by metallic contact areas since such contact areas are controlled toward an electrical connection and not toward optical properties. Such metallic contact areas are situated at one or at two sides of the semiconductor layer sequence. To keep light away from the electrical contact areas or reduce an incidence probability, especially in thin-film light emitting diodes based on InGaAlP or on InAlGaAs, an etching structure with so-called “microprisms” is etched on an opposite side relative to the contact areas. A semiconductor material is removed in places as a result of this etching structure.

Such an etching structure also has the effect that a current spreading layer in places is absent or greatly thinned such that in these regions no or only few charge carriers flow right under the electrical contact areas and from there into the active zone and generate light there. In other words, light generation near the metallic contact areas is avoided. Moreover, the remaining semiconductor material of the semiconductor layer sequence is tapered such that a probability of incidence of light on a surface is increased per distance covered by the light. A coupling-out probability for the light is increased as a result. Moreover, a coupling-out probability is increased by the etching structure and the microprism-like structure associated therewith since the light is reflected and/or scattered at the etching structure. In this case, such an etching structure is generally produced by a plasma etching method, in particular by etching using an inductively coupled plasma, or ICP for short.

In such an etching method, however, it is comparatively difficult to arrive exactly at the correct etching depth. If excessively deep etching is carried out, the active zone is disturbed as a result of which a poorer small-current behavior, a poorer temperature response and initial positive aging may be caused. By contrast, excessively shallow etching leads to poorer coupling-out of light and thus to less efficient components. Therefore, it is important to achieve the appropriate etching depth reproducibly. If the etching is terminated at a set time, that is to say after a predetermined duration, fluctuating etching rates or else layer thickness fluctuations in the semiconductor layer sequence on account of the epitaxial growth make it more difficult to arrive precisely at the suitable etching depth.

The semiconductor chip described comprises the etching signal layer. If the signal constituent is released during etching, then the signal constituent can be detected and the etching of the etching structure is stopped as soon as the signal constituent is detected, or the etching is stopped after a specific time after the appearance or disappearance of the signal constituent in particular in or from an etching plasma. A comparatively thin region between the etching structure and the active zone of semiconductor material is thus attainable in a controllable manner such that in these regions little current is impressed into the active zone and a high light coupling-out efficiency is achieved. In other words, the etching signal layer allows early and exact stopping of the etching during the production of the etching structure.

The active zone may be based on InAlGaP or on InAlGaAs. In this case, the active zone can comprise one or more layers free of one or more of the main components of the corresponding semiconductor material. In other words, the active zone then has a varying material composition.

The etching signal layer may be situated in the p-conducting layer sequence. Preferably, the etching signal layer is then based on InAlGaP or on InAlGaAs. Alternatively or additionally, such an etching signal layer can also be present in the n-conducting layer sequence.

The etching signal layer may be based on In_{1-x-y}Al_{y}GaₓP or on In_{1-x-y}Al_{y}GaₓAs. In this case it holds true that: x+y<1. In this case, the signal constituent is Ga, wherein preferably x is greater than or equal to 0.001 or 0.005 or 0.01 or 0.02. Alternatively or additionally, x is less than or equal to 0.2 or 0.15 or 0.1 or 0.075. It can hold true that y is greater than or equal to 0.3 or 0.35 or 0.4 and/or that y is less than or equal to 0.5 or 0.55 or 0.6.

The thickness of the etching signal layer may be at least 50 nm or 100 nm or 150 nm or 200 nm. Alternatively or additionally, the thickness of the etching signal layer is at most 800 nm or 600 nm or 500 nm or 400 nm.

A concentration of the signal constituent within the etching signal layer may be constant. Constant means, in particular, that a concentration present locally deviates from a mean concentration of the signal constituent by at most 30% or 20% or 10% or 5%. In other words, no targeted concentration fluctuation of the signal constituent is then introduced into the etching signal layer.

The etching signal layer may be situated directly at the active zone, in a direction toward the etching structure and in a direction away from the active zone. In other words, the active zone and the etching signal layer then touch one another.

The etching signal layer may be spaced apart from the active zone. That is to say that the etching signal layer is situated between the active zone and the etching structure, on the one hand, and, on the other hand, at least one further layer of the semiconductor layer sequence is situated between the etching signal layer and the active zone.

A respective further layer may be situated on both sides of the etching signal layer, wherein these two further layers preferably have an identical material composition within the scope of the production tolerances. In particular, these two further layers are free of the signal constituent, or the signal constituent has in these further layers at most 50% or 20% or 10% or 1% or 1% or 10⁻⁴ or 10⁻⁵ of the concentration in the etching signal layer.

A ramp layer may be situated between the etching signal layer and the active zone. The ramp layer is preferably accommodated in the p-type layer sequence. The ramp layer can directly adjoin the active zone. Alternatively or additionally, the ramp layer is also in direct contact with the etching signal layer. Ramp layer means that a concentration of at least one constituent of the ramp layer changes in a ramped fashion, along a growth direction of the semiconductor layer sequence.

The ramp layer may be based on InAlGaP or on InAlGaAs. The ramp layer is based on In_{1-a-b}Al_{b}GaₐP or on In_{1-a-b}Al_{b}GaₐAs where a+b<1. The In content 1−a−b is preferably constant in the ramp layer, within the scope of the production tolerances.

In this case, the following preferably holds true at a side of the ramp layer which is closest to the active zone: 0.10≦a or 0.15≦a or 0.2≦a and/or a≦0.3 or a≦0.35 or a≦0.4. The same values alternatively or additionally hold true for b. The sum of a and b is preferably greater than or equal to 0.3 or 0.4 or 0.5 and/or less than or equal to 0.65 or 0.6 or 0.55.

For a side of the ramp layer facing away from the active zone it preferably holds true that a≦0.1 or a≦0.05 or a≦0.02 or a≦0.005. Alternatively or additionally it holds true that 0.35≦b or 0.4≦b or 0.45≦b and/or b≦0.65 or b≦0.6 or b≦0.55.

The aluminum content b in the ramp may rise monotonically or strictly monotonically in a direction away from the active zone. Alternatively or additionally, the aluminum content b in the active zone can change continuously, that is to say without jumps. In particular, the aluminum content b in the ramp changes linearly or approximately linearly.

The ramp layer may have a thickness of at least 50 nm or 150 nm or 200 nm. Alternatively or additionally, the thickness is at most 800 nm or 600 nm or 400 nm.

The semiconductor chip may comprise a p-type electrode at the p-conducting layer sequence. Furthermore, the semiconductor chip includes an n-type electrode at the n-conducting layer sequence. The two electrodes can directly adjoin the associated layer sequence. Preferably, the two electrodes are metallic electrodes, that is to say that the electrodes are formed by one or more layers composed of a metal or a metal alloy. The p-type electrode can comprise different materials than the n-type electrode.

The electrodes may be or at least one of the electrodes may be structured to form a multiplicity of strips. In this case, strips means, in particular, that, as seen in a plan view of the semiconductor layer sequence, a longitudinal extent of the strip exceeds a width of the strip by at least a factor of 10 or 100. In this case, the individual strips can connect to one another and/or to a contact region for external electrical contacting by connecting webs or further elements. Instead of strips, in particular the p-type electrode can also be structured to form a multiplicity of smaller island-shaped regions or islands.

The strips and the island-shaped regions may impress current into the semiconductor layer sequence. In other words, no layer provided for current isolation is then situated between the strips or island-shaped regions and the semiconductor layer sequence. Such an isolation layer can be fitted at the electrical contact regions for external electrical contacting and/or at the connecting webs, which are then correspondingly not provided to impress current.

The two electrodes may not mutually overlap one another, as seen in plan view. In other words, the island-shaped regions can be situated between the strips or, in two electrodes structured to form strips, the electrodes can intermesh in a comblike fashion, wherein the strips then do not mutually cover or shade one another, as seen in a plan view of the semiconductor layer sequence.

The etching structure may be situated in the p-conducting layer sequence only between adjacent strips or island-shaped regions of the p-type electrode, as seen in plan view. In other words, no etching structure is then present in the region of the strips or of the island-shaped regions of the p-type electrode. Therefore, as seen in plan view, the etching signal layer can be completely present below the strips or the island-shaped regions and the p-type electrode.

A roughening may be present between adjacent strips at the n-type electrode in the n-conducting layer sequence. It is possible for the etching structure in the p-conducting layer sequence to overlap the roughening in the n-conducting layer sequence in places, as seen in a plan view of the semiconductor layer sequence.

The semiconductor chip may be a thin-film semiconductor chip. That is to say that the semiconductor chip is then free of a growth substrate of the semiconductor layer sequence. For a mechanical stabilization and preferably also for an electrical contacting of the semiconductor layer sequence, a carrier different from the growth substrate is then present. In particular, the carrier is situated at the p-conducting layer sequence and/or at the p-type electrode. In this case, the n-conducting layer sequence is preferably provided to couple out radiation from the semiconductor layer sequence.

The n-conducting layer sequence and the p-conducting layer sequence may be doped. The dopant concentration is preferably at least 1×10¹⁶/cm³ or 1×10¹⁷/cm³ or 1×10¹⁸/cm³ and/or at most 3×10¹⁶/cm³ or 3×10¹⁷/cm³ or 3×10¹⁸/cm³. In this case, a p-doping is effected with magnesium, for example. It is also possible for a plurality of dopants in combination to be present.

A distance between the etching signal layer and the active zone may be at least 100 nm or 200 nm or 300 nm. Alternatively or additionally, the distance is at most 800 nm or 600 nm or 400 nm.

The etching structure may have a mean depth of at least 0.25 μm or 0.75 μm and/or of at most 5 μm or 3.5 μm. Alternatively or additionally, a mean width of the etching structure is at least 5 μm or 10 μm or 20 μm and/or at most 150 μm or 100 μm or 40 μm. In this case, the etching structure preferably has oblique side surfaces and a planar base surface within the scope of the production tolerances. An angle between the side surfaces and a growth direction of the semiconductor layer sequence is preferably at least 15° or 30° or 45° or 55° and/or at most 85° or 75° or 60° or 45°.

The roughening may have a mean depth or mean structure size or mean roughness of at least 200 nm or 250 nm or 350 nm or 500 nm. Alternatively or additionally, this value is at most 5 μm or 2.5 μm or 1 μm or 0.75 μm.

A distance between the etching structure and the active zone may be at least 100 nm or 200 nm or 300 nm. Alternatively or additionally, the distance is at most 750 nm or 500 nm or 350 nm. In this case, the distance corresponds in particular to a minimum thickness of a material of the semiconductor layer sequence between the etching structure and the active zone.

We also provide a method of producing an optoelectronic semiconductor chip. In particular an optoelectronic semiconductor chip in conjunction with one or more of the examples mentioned above is produced by the method. Therefore, features of the semiconductor chip are also disclosed for the method, and vice versa.

The etching structure may be created in the semiconductor layer sequence by dry-chemical etching. The etching is preferably etching using an inductively coupled plasma.

The signal constituent of the etching signal layer may be detected during the etching and during the production of the etching structure and measurement, in particular continuous measurement, is carried out toward the signal constituent. The etching is controlled and/or ended by an evaluation of the measurement of the signal constituent. By way of example, the etching is ended if the signal constituent is measured. Likewise, the etching can be ended after a specific time after the occurrence of the signal constituent. Moreover, it is possible to end the etching only if a measurement signal of the signal constituent becomes smaller or disappears, that is to say if the etching signal layer is etched through.

Our optoelectronic semiconductor chips are explained in greater detail below on the basis of examples with reference to the drawings. In this case, identical reference signs indicate identical elements in the individual figures. In this case, however, relations to scale are not illustrated. Rather, individual elements may be illustrated with exaggerated size to afford a better understanding.

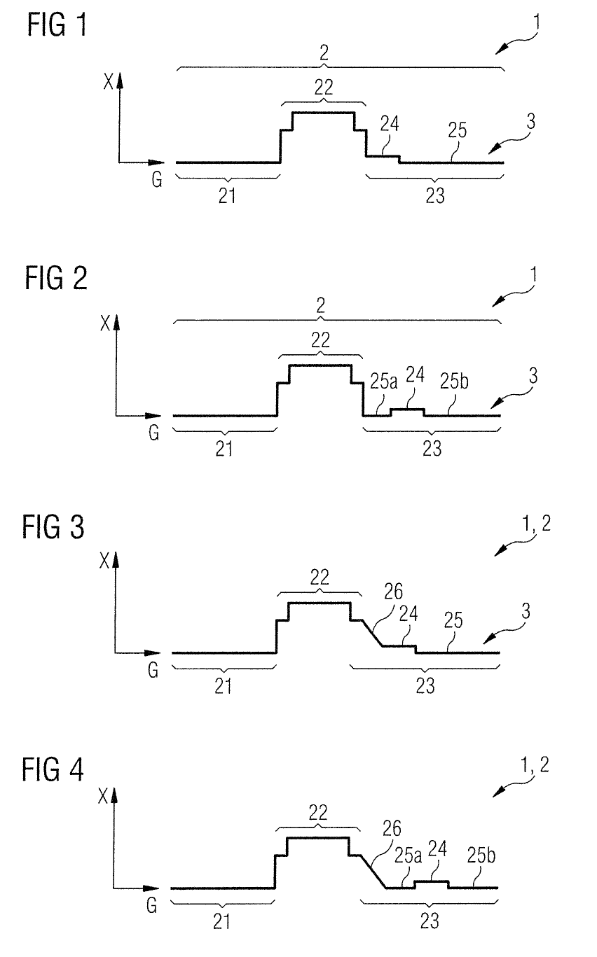

FIG. 1 illustrates a construction of a semiconductor layer sequence 2 for an optoelectronic semiconductor chip 1 in a schematic illustration. In this case, the illustration shows a proportion x of a signal constituent in the semiconductor layer sequence 2 along a growth direction G of the semiconductor layer sequence 2. The semiconductor chip 1 in this case is a light emitting diode chip that preferably generates yellow or red light.

The semiconductor layer sequence 2 has an n-conducting layer sequence 21. In a departure from the illustration, the n-conducting layer sequence 21 can comprise a plurality of partial layers. The n-conducting layer sequence 21 is based on InAlP, for example. A thickness of the n-conducting layer sequence 21 is preferably at least 1 μm or 2 μm or 3 μm and/or at most 10 μm or 7 μm or 5 μm, as also in all the other examples.

The n-conducting layer sequence 21 is succeeded by an active zone 22 along the growth direction G. The active zone 22 is illustrated merely in a greatly simplified manner and preferably comprises a plurality of quantum wells and interposed barrier layers and preferably furthermore also barrier layers for holes and for electrons. The active zone 22 is based on In_{1-x-y}Al_{y}GaₓP. Depending on the emission wavelength it holds true here for the quantum wells in the active zone 22 that 0.15≦x or 0.2≦x and/or x≦0.5 or x≦0.4. For the barrier layers in the active zone 22 it holds true that, depending on the emission wavelength, preferably 0.15≦x or 0.2≦x and/or x≦0.4 or x≦0.35. An indium content 1−x−y is approximately 50% and thus 0.5 with a tolerance of preferably at most 0.1 or 0.05. A thickness of the active zone 22 is, for example, at least 300 nm or 100 nm and/or at most 1000 nm or 2000 nm.

The active zone 22 is succeeded directly by a p-conducting layer sequence 23 along the growth direction G. In this case, a first layer of the p-conducting layer sequence 23 is formed by a p-doped etching signal layer 24. A thickness of the etching signal layer 24 is preferably approximately 300 nm. The etching signal layer 24 is based on In_{1-x-y}Al_{y}GaₓP where x≈0.05 and y≈0.45.

The Ga content x of the etching signal layer 24, corresponding to the signal constituent, is chosen such that, on the one hand, an effective charge carrier barrier is formed relative to the active zone 22 and, on the other hand, a sufficient measurement signal with regard to the signal constituent results during the etching of the semiconductor layer sequence 2 during the exposure of the etching signal layer 24. Accordingly, the Ga content x is comparatively small to achieve a sufficient charge carrier trapping in the active zone 22.

The etching signal layer 24 is succeeded by a further p-type layer 25 along the growth direction G. The p-type layer 25 is based on InAlP. A thickness of the further p-type layer 25 is at least regionally preferably at least 500 nm or 1000 nm or 1500 nm and/or at most 3000 nm or 2000 nm.

The p-conducting layer sequence 23 can have, at a side of the further p-type layer 25 facing away from the active zone 22, additional layers (not illustrated), for example, for better electrical contacting of the semiconductor layer sequence 2. The additional layers are in each case not depicted to simplify the illustration.

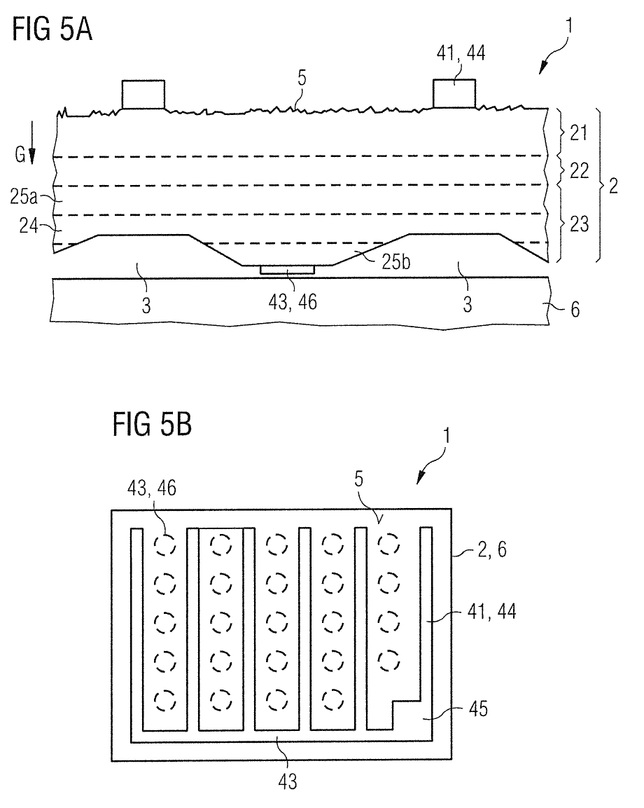

An etching structure 3 is produced at the p-conducting layer sequence 23, see also the sectional illustration in FIG. 5A and the schematic plan view in FIG. 5B. The etching structure at the p-conducting layer sequence 23 is produced in regions between a p-type electrode 43 structured to form islands 46. As a result of the etching structure 3 and thus as a result of the regional removal of the p-type layer 25 succeeding the etching signal layer 24 along the growth direction G, a current spreading is locally prevented and a radiation coupling-out efficiency is increased. Instead of islands 46, the p-type electrode 43, unlike in the depiction shown, can also be structured to form strips, analogously to the n-type electrode 41.

In accordance with FIG. 5A, a growth substrate is removed from the semiconductor layer sequence 2. Instead, a carrier 6 for electrical contacting and mechanical stabilization is fitted at the p-conducting semiconductor layer sequence 23. At the n-conducting layer sequence 21 there are situated an n-type electrode 41 structured to form webs 44 and an electrical contact area 45, in particular for fitting a bond wire (not depicted). A roughening 5 is optionally produced at the n-conducting layer sequence 21. Unlike in the illustration shown, an etching signal layer can likewise be present for producing the roughening 5.

FIG. 2 illustrates a further example of the semiconductor chip 1. In accordance with FIG. 2, between the active zone 22 and the etching signal layer 24 there is situated a p-type layer 25a of the same composition as at a side of the etching signal layer 24 facing away from the active zone 22. The p-type layers 25a, 25b thus have an identical material composition within the scope of the production tolerances. On account of the p-type layer 25a situated between the active zone 22 and the etching signal layer 24, a full barrier height toward the active zone 22 can be fully utilized, as a result of which an improved charge carrier trapping in the active zone 22 can be realized. A thickness of the p-type layer 25a is, for example, at least 50 nm or 100 nm and/or at most 500 nm or 400 nm, preferably approximately 300 nm. The construction of the semiconductor layer sequence 2, as illustrated in FIG. 2, also corresponds to the construction of the semiconductor layer sequence as depicted in FIG. 5A.

In comparison with the semiconductor layer sequence 2 in accordance with FIG. 1, the etching signal layer 24 is thus situated further away from the active zone 22. To nevertheless achieve a small remaining thickness of the p-conducting layer sequence 23 in regions with the etching structure 3, it is possible for the etching of the etching structure 3 to be carried out only in a time-delayed manner after an occurrence of the signal constituent, that is to say Ga, or for the etching to be stopped in response to a falling signal of the signal constituent. If overetching at a set time is effected, then this is nevertheless carried out with a comparatively high precision since a proportion of the time of the overetching is small in comparison with a total etching time, such that an influence of a fluctuating etching rate or a thickness fluctuation in the semiconductor layer sequence 2 on account of epitaxy tolerances is correspondingly reduced.

Consequently, in a departure from the illustration in FIG. 5A, the etching structure 3 can also penetrate through the etching signal layer 24 in places. Likewise, the etching signal layer 24 can be completely removed in the regions between the webs 44 of the p-type electrode 43.

In the example in accordance with FIG. 3, a ramp layer 26 is situated between the active zone 22 and the etching signal layer 24. In the ramp layer 26, the Ga proportion x falls linearly along the growth direction G. In this case, an indium content remains approximately constant, such that an aluminum proportion in the ramp layer 26 rises along the growth direction G. A thickness of the ramp layer 26 is, for example, approximately 300 nm. In the ramp layer 26, therefore, in contrast to the etching signal layer 24, a proportion of aluminum and gallium is varied.

In the example in accordance with FIG. 4, there is situated between the ramp layer 26 and the etching signal layer 24 the intervening layer 25a, analogously to the example in accordance with FIG. 2.

Our semiconductor chips and methods described here are not restricted by the description on the basis of the examples. Rather, this disclosure encompasses any novel feature and also any combination of features, which in particular includes any combination of features in the appended claims, even if the feature or combination itself is not explicitly specified in the claims or examples.

This application claims priority of DE 10 2014 107 385.1, the subject matter of which is hereby incorporated by reference.

1-14. (canceled)

15. An optoelectronic semiconductor chip which is a light emitting diode comprising a semiconductor layer sequence, wherein the semiconductor layer sequence has:
an n-conducting layer sequence,
a p-conducting layer sequence,
an active zone situated between the n-conducting layer sequence and the p-conducting layer sequence,
at least one etching signal layer in the p-conducting layer sequence and/or in the n-conducting layer sequence, and
an etching structure at a side of the etching signal layer facing away from the active zone, wherein
the etching structure extends at least right into the etching signal layer,
the etching signal layer has a signal constituent,
the active zone generates radiation and is based on InAlGaP or on InAlGaAs,
the etching signal layer is situated in the p-conducting layer sequence and is based on In_{1-x-y}Al_{y}GaₓP or on In_{1-x-y}Al_{y}GaₓAs where x+y<1,
the signal constituent is Ga and 0.005≦x≦0.2,
the signal constituent is not present in the layer adjoining the etching signal layer in a direction toward the etching structure,
a thickness of the etching signal layer is 50 nm to 800 nm, and
as a result of the etching structure a material of the etching signal layer is partly removed.

16. The optoelectronic semiconductor chip according to claim 29,
wherein the active zone generates radiation and is based on InAlGaP or on InAlGaAs, wherein
the etching signal layer is situated in the p-conducting layer sequence and is based on In_{1-x-y}Al_{y}GaₓP or on In_{1-x-y}Al_{y}GaₓAs where x+y<1,
the signal constituent is Ga and 0.005≦x≦0.2,
the signal constituent is not present in the layer adjoining the etching signal layer in a direction toward the etching structure, and
a thickness of the etching signal layer is 50 nm to 800 nm.

17. The optoelectronic semiconductor chip according to claim 15, wherein a concentration of the signal constituent in the etching signal layer is constant, with a tolerance of at most 20% of a mean concentration of the signal constituent in the etching signal layer.

18. The optoelectronic semiconductor chip according to claim 15, wherein the etching signal layer is directly adjacent to the active zone, in a direction toward the etching structure.

19. The optoelectronic semiconductor chip according to claim 15, wherein the etching signal layer is spaced apart from the active zone.

20. The optoelectronic semiconductor chip according to claim 19,
wherein a respective further layer is situated on both sides of the etching signal layer and these further layers have an identical material composition, and
the further layers are free of the signal constituent.

21. The optoelectronic semiconductor chip according to claim 19,
wherein a ramp layer based on In_{1-a-b}Al_{b}GaₐP or on In_{1-a-b}Al_{b}GaₐAs where a+b<1 is situated between the etching signal layer and the active zone in the p-type layer sequence,
in a direction away from the active zone in the ramp layer, the Al content b rises monotonically or strictly monotonically and the ramp layer directly adjoins the active zone,
at the active zone it holds true that: 0.15≦a≦0.35 and 0.15≦b≦0.35 and 0.4≦a+b≦0.6, and
at a side of the ramp layer facing away from the active zone it holds true that: a≦0.05 and 0.4≦b≦0.6.

22. The optoelectronic semiconductor chip according to claim 21, wherein in the ramp layer the Al content b changes linearly and the indium content 1−a−b is constant, and a thickness of the ramp layer is 50 nm to 500 nm.

23. The optoelectronic semiconductor chip according to claim 15, further comprising a p-type electrode at the p-conducting layer sequence and an n-type electrode at the n-conducting layer sequence,
wherein the electrodes are structured to form a multiplicity of strips or islands and the strips or the islands of both electrodes are arranged in a manner free of overlap in a radiation-generating region, as seen in plan view, and
the etching structure is present in the p-conducting layer sequence in the radiation-generating region only between adjacent strips or islands of the p-type electrode.

24. The optoelectronic semiconductor chip according to claim 23, wherein a roughening is present between adjacent strips of the n-type electrode in the n-conducting layer sequence.

25. The optoelectronic semiconductor chip according to claim 15, which is free of a growth substrate of the semiconductor layer sequence,
wherein radiation is coupled out at the n-conducting layer sequence, and wherein a carrier is situated at the p-conducting layer sequence.

26. The optoelectronic semiconductor chip according to claim 15, wherein
the etching signal layer is based on In_{1-x-y}Al_{y}GaₓP where 0.35≦y≦0.55 and where 0.02≦x≦0.15 and has a thickness of 150 nm to 500 nm and is doped with Mg with a concentration of 1×10¹⁶ cm⁻³ to 3×10¹⁸ cm⁻³,
the p-type layer adjoining the etching signal layer is based on In_{1-x-y}Al_{y}GaₓP where 0.4≦y≦0.6 and where x≦0.001,
a distance between the etching signal layer and the active zone is 200 nm to 600 nm,
the etching structure has a mean depth of 250 nm to 5 μm, and
a distance between the etching structure and the active zone is 100 nm to 500 nm.

27. A method in which an optoelectronic semiconductor chip according to claim 15 is produced comprising:
providing the semiconductor layer sequence having the n-conducting layer sequence, the p-conducting layer sequence, the active zone and the etching signal layer,
producing the etching structure by dry-chemical etching of the semiconductor layer sequence, and
completing the semiconductor chip, wherein
during the etching measurement is carried out toward the signal constituent of the etching signal layer, and
the etching is ended by an evaluation of the measurement of the signal constituent.

28. The method according to claim 27,
wherein the etching is etching with inductively coupled plasma, and
during the etching the etching signal layer is completely penetrated in places.

29. An optoelectronic semiconductor chip comprising a semiconductor layer sequence, wherein the semiconductor layer sequence has:
an n-conducting layer sequence,
a p-conducting layer sequence,
an active zone situated between the n-conducting layer sequence and the p-conducting layer sequence,
at least one etching signal layer in the p-conducting layer sequence and/or in the n-conducting layer sequence,
an etching structure at a side of the etching signal layer facing away from the active zone,
the etching structure extends at least right into the etching signal layer, and
the etching signal layer has a signal constituent reduced by at least a factor of two in a layer adjoining the etching signal layer in a direction toward the etching structure.
